(19) United States
(12) Patent Application Publication
(10) Pub. No.: US 2007/0242837 A1
(43) Pub. Date: Oct. 18, 2007

(54) Speed- and User-Dependent Timbre and Dynamic Range Control Method, Apparatus and System for Automotive Audio Reproduction Systems

(76) Inventor: Geoffrey Glen, Vinderup (DK)

Correspondence Address: STITES & HARBISON PLLC, 1199 NORTH FAIRFAX STREET, SUITE 900, ALEXANDRIA, VA, 22314, US

(21) Appl. No.: 11/573,829

(22) PCT Filed: Aug. 16, 2005
(86) PCT No.: PCT/IB05/52696

§ 371 Date: Feb. 16, 2007

(30) Foreign Application Priority Data
Aug. 16, 2004 (EP) 04019395.5
Nov. 22, 2004 (DK) PA 2004 01815

(51) Int. Cl. H03G 5/00

(52) U.S. Cl. 381/101

(57) ABSTRACT

Typically, changes in timbre in an audio reproduction system use analogue or digital filters, either shelving filters (as in the case of bass, treble and loudness controllers) and/or peaking filters (as in the case of speed-and noise-compensation in automotive systems). A problem associated with this implementation lies in the audibility of the phase shift caused by these filters. According to the invention, this and further problems are solved by utilising the crossover network of the system itself—with level adjustable output signals—to attain desired timbre and/or dynamic range adjustments and hence avoiding undesirable phase effects of the traditional bass and treble control filters. An input signal (18) is according to an embodiment of the invention divided by a cross over network (20) into a number of frequency bands and applied via level control means (21, 22, 23) and separate power amplifiers (24, 25, 26) to loudspeaker drivers (27, 28, 29). In this manner, the mentioned phase shifts can be avoided and by proper control of the level adjustment means by a frequency-dependent analysis and weighting network (30), desired adjustment of timbre and dynamic range of the audio reproduction can be achieved. Also control dependent on vehicle speed and/or background noise can be incorporated into the system..

### TECHNICAL FIELD

The present invention relates generally to methods, devices and systems for use in adjusting the timbre, dynamic range, and level of a reproduced audio signal and specifically to such methods, devices and systems used in automotive audio reproduction systems.

### BACKGROUND OF THE INVENTION

Audio reproduction systems for automotive use traditionally have been equipped with systems that control the overall basic timbre and/or dynamic range of program material reproduced by the system. These systems can be user-controlled as exemplified in the following cases:
1. Bass level adjustment
2. Treble level adjustment
3. “Loudness” compensation (i.e. a frequency-dependent gain applied at low listening levels)

Alternatively, they may be automatically adjusted as in the following examples:
1. Auto-loudness (i.e. a loudness function as described above that is invoked automatically by the system according to the user-determined listening level)
2. Speed- and noise-compensation in automotive audio

The last example is of paramount importance in automotive systems, since human perception of an auditory signal is contingent upon other concurrent signals that are present, whether coherent or incoherent with the original signal. For example, the perceived qualities of a signal produced by an automotive audio reproduction system will differ in the presence or absence of differing background noises (such as are caused by the engine, tires, wind, ventilation system, adjacent vehicles, etc.). These differences will also change with differences in output signal level, caused either by changes such as in the level of the signal being reproduced (i.e. variations in the overall level of the signal before any gain is applied to it) and/or by the user-determined volume setting.

In order to maintain constancy in the perceived auditory attributes of an audio reproduction system in the presence of varying amounts of background noise, various physical attributes of the signal must be modified appropriately. Traditionally, these physical changes have comprised of processing methods (such as frequency-independent gain, equalization and/or compression) applied to the entire reproduction signal. A schematic block diagram of a traditional system for timbre adjustment of a type which can be found in many traditional automotive systems is shown in FIG. 1 and described in some detail in the detailed description of the invention.

A similar implementation can be used in the case of a typical loudness control, which is found in most traditional high-fidelity playback systems for domestic or automotive use, in which the gain of one or more equalization stages is controlled using a toggle switch. It is also well-known in such equipment to apply automatic loudness adjustment, where the gain of the equalization stage(s) is determined by the overall user-controlled gain setting.

Typically, changes in timbre in an audio reproduction system use analogue or digital filters, either shelving filters (as in the case of bass, treble and loudness controllers) and/or peaking filters (as in the case of speed- and noise-compensation in automotive systems). These filters are typically implemented as minimum-phase devices due to facility of development and implementation.

One problem associated with this implementation lies in the audibility of the phase shift caused by these filters. For example, a minimum-phase implementation of a shelving filter has a characteristic phase response that has detrimental effects on the reproduced audio signal. Examples of the phase characteristics of such filters are shown in FIGS. 2b and 3b of the detailed description. Thus, although the desired magnitude response is attained, the traditional system suffers from a degraded audio quality due to phase response artefacts such as an audible “ringing” effect.

Also, changes in the gain of the system for the purposes of automatic compensation of reproduction level and dynamic range according to speed or background noise conditions are typically frequency-independent. That is to say, signal level adjustment or signal compression is applied to the signal's entire frequency bandwidth. The result is a control of the signal's level and dynamic range, however, this control is applied to all frequency bands in the signal, resulting in at least two possible unwanted artefacts:
1. Audible gain changes due to components occupying one frequency band modulating components in a second frequency band.
2. Level and/or dynamic range modifications applied to a frequency band that is unaffected by background noise and therefore requires no processing.

### SUMMARY OF THE INVENTION

Based on the above background, it is the objective of the present invention to provide a method and corresponding devices and systems that do not suffer from or at least reduce said detrimental effects of traditional filters and wide-band level control.

In its broadest aspect, the above objective is attained according to the invention by utilising the crossover network itself—with level adjustable output signals—to attain the desired timbre and/or dynamic range adjustments and hence avoiding the undesirable phase effects of the traditional bass and treble control filters.

The improved methods, devices, and systems according to the present invention could find use within all fields of audio reproduction in automotive, domestic and professional listening environments. However, they are particularly applicable to the field of automotive audio.

In a preferred embodiment of the present invention, an active loudspeaker system is used in an automotive audio reproduction system, i.e. a device comprising an audio input, a crossover network consisting of a plurality of filter banks whose input is a wide-band audio signal and whose outputs are frequency band-limited versions of the input signal. These outputs are fed individually to the inputs of discrete power amplifiers, and the output signal of each of these power amplifiers is provided to a separate loudspeaker driver. Each loudspeaker driver in the system is thus connected to a single power amplifier with its own adjustable gain, independent of the other amplifiers. The overall timbre of the entire loudspeaker system is, in part, determined by the relationship between the gain values of the various amplifiers used to drive the entire loudspeaker system.

Since each amplifier is provided with a frequency band-limited signal, it is possible to use offsets of the independent gain of each amplification stage to manipulate the overall timbre of the system, thus replacing the filters applied to the entire signal as is used in traditional systems. The resulting magnitude response of the entire system may be similar to the magnitude response of a traditional system, however, there is no resulting phase distortion, thus providing a perceptual improvement over the traditional filter-based system.

In addition, modulation of the independent gain of each amplification stage can be employed to control the level of the system as well as the frequency-dependent dynamic range of the signal. This dynamic range control would then modulate the level of each frequency band independently according to control signals determined by the signals themselves, the desired output level of the system and the background noise. The result is a signal with independent appropriate control of the level and dynamic range in a plurality of frequency bands, providing less interference across frequency bands in the signal and therefore fewer undesirable audible artefacts.

Thus, according to an embodiment of the invention, there is provided a timbre and level adjustment method comprising the following steps:
a) subdividing an audio signal (Si) into N frequency bands (N1, N2, . . . Nn), each of said bands providing a frequency band-limited output signal (So1, So2, . . . Son);
b) adjusting the level (Lo1, Lo2, . . . Lon) of each of said output signals (So1, So2, . . . Son) independently; and
c) providing each of said adjusted output signals (So1, So2, . . . Son) to separate power amplifiers connected to individual loudspeaker drivers for converting the level-adjusted output signals to sound signals emitted by each of said transducers.

Furthermore, according to the present invention, there is provided a timbre and level adjustment device for receiving an input signal (Si) and providing N level-adjusted output signals, the device comprising means for subdividing said input signal (Si) into N frequency bands (N1, N2, . . . Nn), each of said bands providing a frequency band-limited output signal (So1, So2, . . . Son), where each of said frequency band-limited signals (So1, So2, . . . Son) are provided to adjustment means for adjusting the level (L01, Lo2, . . . Lon) of each of said band-limited output signals (So1, So2, . . . Son), whereby said N level-adjusted output signals are provided.

Just as in the case of traditional systems, the individual instantaneous gain of each power amplifier can be adjusted either manually or by automatic means. In automotive applications, the individual gains can also take account of aspects such as the signal's level, the varying speed of the vehicle, and the overall sound level in the cabin or suitably filtered versions thereof.

Furthermore, the method may comprise the additional step of maintaining the maximum level of the output signals from the individual power amplifiers below given threshold values, whereby the risk of overloading of one or more of the loudspeaker drivers can be reduced or eliminated. Means to the same effect can be introduced in the device according to the invention, for instance, by using the individual output signals—possibly after suitable processing—to control the gain of each individual frequency band.

The method and device according to the above embodiment of the present invention provides a number of advantages, among which should be mentioned generally improved sound quality, lower Digital Signal Processing (DSP) requirements, and easier implementation of interpolation between frequency-dependent gain values.

It should be noted that the broadest aspect of the invention as outlined initially may also be embodied by other means than those described above, e.g. without separate power amplifiers to drive each of the loudspeaker drivers. Thus, both an embodiment comprising separate power amplifiers for each loudspeaker driver and an embodiment comprising only one common power amplifier will be described in the following detailed description of the invention.

It should furthermore be noted that the method and systems according to the present invention both in principle and in any practical embodiment hereof may find use in one, more or all of the individual channels of a multi-channel system (stereophonic, quadraphonic, etc., either with the same parameters and functions (for instance number of loudspeaker drivers used in that channel, cross-over frequencies of cross-over networks, various gain characteristics, etc.) for all channels or with dedicated set of parameters for each channel or groups of channels.

### BRIEF DESCRIPTION OF THE FIGURES

In the following, various embodiments of timbre- and level- adjustment devices according to the present invention will be described in detail with reference to the drawing comprising the following Figures:

FIG. 1. A prior art timbre adjustment system comprising separate low frequency (bass) and high frequency (treble) controls using equalization.

FIG. 2a. Gain adjustment (in dB) as a function of frequency for a traditional bass control filter.

FIG. 2b. Phase adjustment (in degrees) as a function of frequency for the filter described in FIG. 2a.

FIG. 3. A prior art speed-dependent equalisation and dynamic range adjustment system for automotive audio reproduction.

FIG. 4a. Gain adjustment (in dB) as a function of frequency for a traditional peaking filter.

FIG. 4b. Phase adjustment (in degrees) as a function of frequency for the filter described in FIG. 3a.

FIG. 5. An embodiment of a timbre- and level-adjustment device according to the present invention.

FIG. 6a. Gain adjustment (in dB) as a function of frequency for gain changes in one frequency band for an embodiment of the invention shown in FIG. 5.

FIG. 6b Phase adjustment (in degrees) as a function of frequency for the embodiment of the invention described in FIG. 5a.

FIG. 7. Two possible examples of the gain adjustment (in dB) for a band-limited low-frequency output for changes in a Bass control for an embodiment of the invention shown in FIG. 5.

FIG. 8. Two possible examples of the gain adjustment (in dB) for a band-limited high-frequency output for changes in a Treble control for an embodiment of the invention shown in FIG. 5.

FIG. 9. The gain applied to a band-limited low-frequency output for changes in overall frequency-independent desired output level for an embodiment of the invention shown in FIG. 5, showing an example of an automatic “loudness” control.

FIG. 10. The gain applied to a band-limited output for changes in overall frequency-independent desired output level and vehicle speed for an embodiment of the invention in an automotive audio system shown in FIG. 5, showing an example of a vehicular speed-compensation system.

FIG. 11. The gain applied to a band-limited output for changes in overall frequency-independent desired output level and independent background noise for an embodiment of the invention shown in FIG. 5, showing an example of a noise-compensation system.

FIG. 12. An embodiment of the invention for a passive loudspeaker.

### DETAILED DESCRIPTION OF AN EMBODIMENT OF THE INVENTION

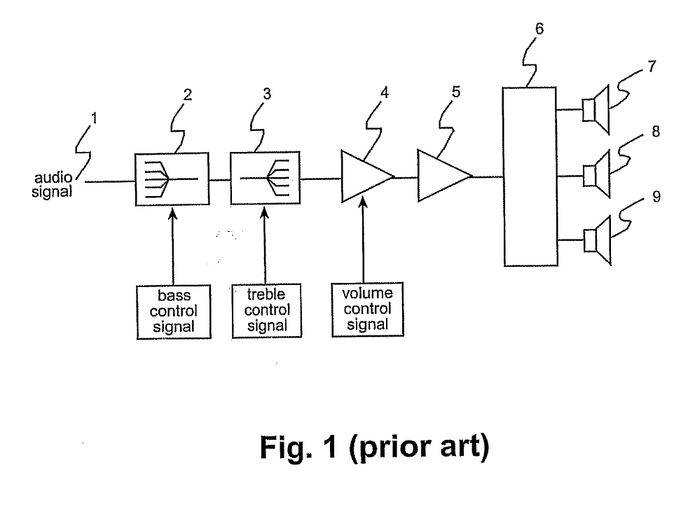

With reference to FIG. 1, there is shown a traditional timbre-adjustment device (tone control) of a type well-known within the field of audio reproduction techniques for driving a passive loudspeaker. An audio signal is provided at an input terminal 1 to a bass control unit 2 followed by a treble control unit 3. The characteristics of these control units are determined by gain parameters provided to the two shelving filters used in these control units. The gain characteristics are indicated in the units 2 and 3 in FIG. 1 in a schematic manner. The output signal from the treble control unit is provided to a power amplifier 5 via a gain control 4, controlling the overall gain of the system. The output of the power amplifier is connected to a frequency crossover network 6. The frequency band-limited output signals from the crossover device are individually connected to loudspeakers 7, 8, and 9.

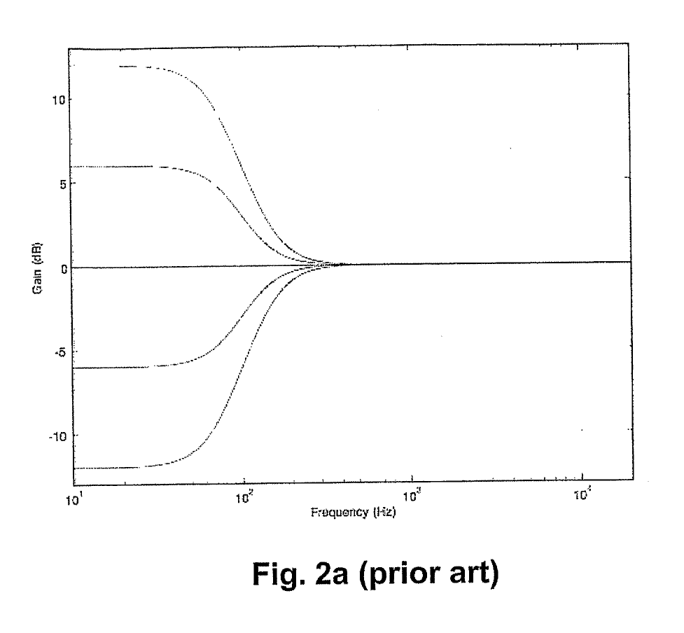

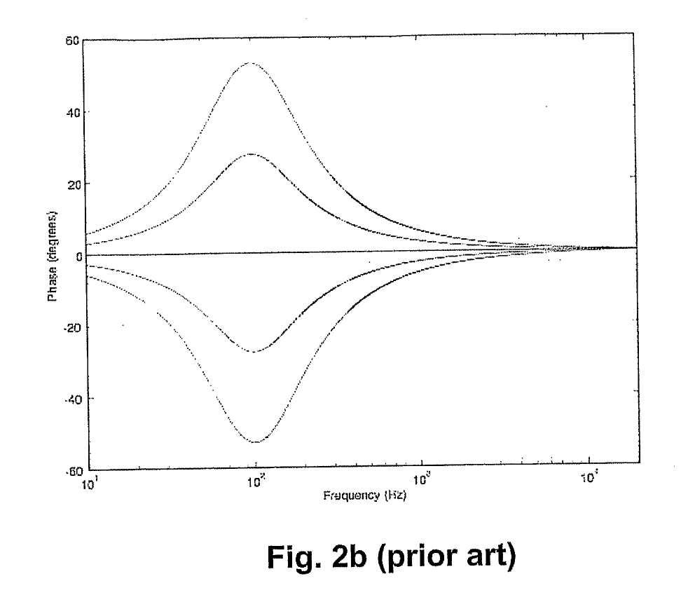

As mentioned in the summary of the invention, a drawback of this implementation lies in the detrimental effect of the phase characteristics of the shelving filters used in the bass and treble control units, An example of the gain characteristics (i.e. gain (dB) as a function of frequency) and the corresponding phase characteristics (i.e. phase (degrees) as a function of frequency) are shown in FIGS. 2a and 2b, respectively, (for the bass control unit) for various settings of the gain of the filters. Two frequency bands exhibiting very high slopes in the phase response can be observed on either side of the marked peak in the phase response. These extreme slopes in the phase response correspond to undesirable audible artefacts such as “ringing,” deteriorating the overall sound quality of the system.

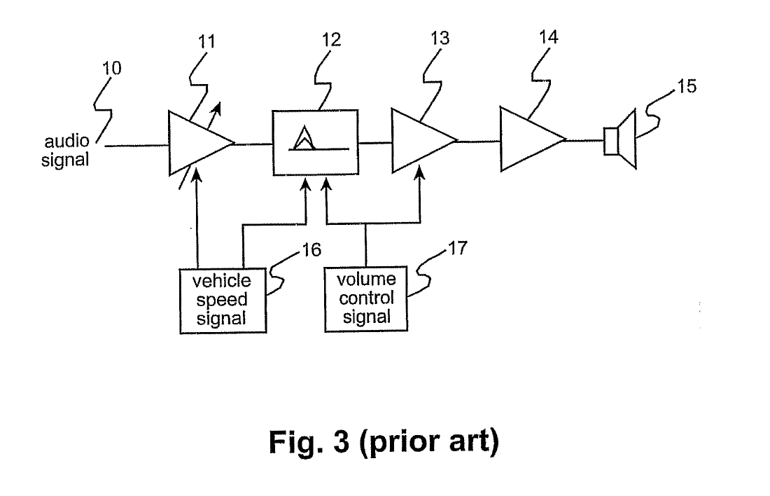

With reference to FIG. 3 there is shown a traditional speed- and noise-dependent dynamic range and equalisation device of a type well-known within the field of automotive audio A full-frequency bandwidth audio signal is provided at an input terminal 10 to a gain control device 11. The gain of said gain control device is determined by a separate control signal 16 determined by the speed of the vehicle such that, at higher speeds, there is an increase in overall gain and a reduction in dynamic range of the program material. The output of the gain control device is connected to the input of a dynamic equaliser 12. The gain of this equaliser is determined by the speed-dependent control signal as well as the user-determined level control signal 17 such that, at higher speeds and/or at lower user-determined listening levels, there is an increased gain in a frequency band dependent on the characteristics of the equalisation device. The output of the equalisation device is connected to the input of a gain-control device 13 whose gain is determined by the user. The output of the gain control device is provided to a power amplifier 14. The output of said power amplifier is connected to a loudspeaker 15 for the purpose of converting electrical into mechanical energy.

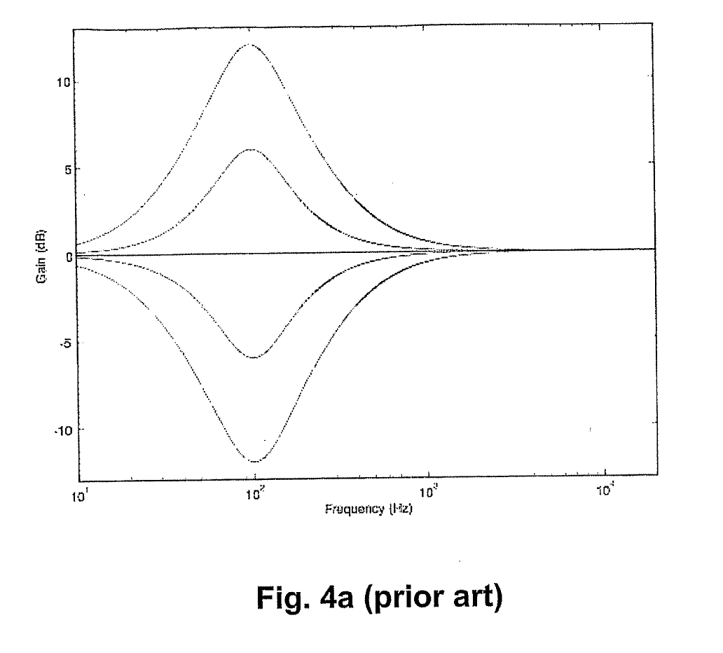

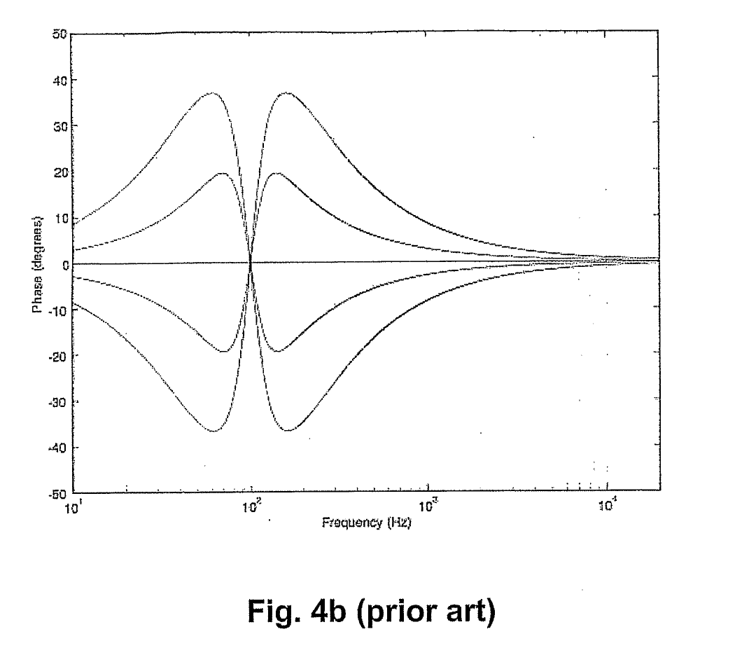

A drawback of this implementation lies in the detrimental effect of the possible phase characteristics of the dynamic equalisation filters used in the system. An example of the gain characteristics (i.e. gain (dB) as a function of frequency) and the corresponding phase characteristics (i.e. phase (degrees) as a function of frequency) is shown in FIGS. 4a and 4b, respectively, for various settings of the gain of the filters. There can be seen a frequency band which exhibits a high slope of the phase characteristic, for all gain settings of the equaliser.

As mentioned in the summary of the invention, a second drawback of this implementation lies in the detrimental effect of applying a gain modulated by vehicle speed, background noise, or signal level to the entire frequency bandwidth of the program material.

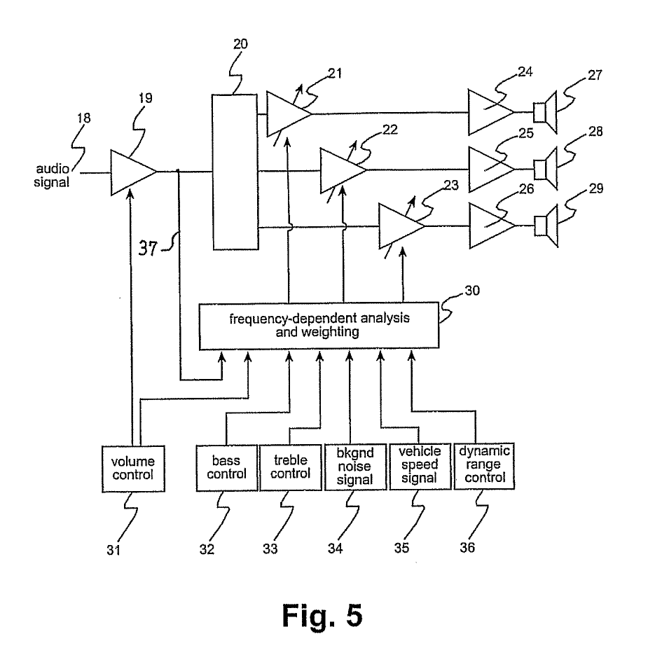

A block diagram of an embodiment of a device according to the invention implementing the method defined by claim 1 of the present application is shown in FIG. 5. A full-frequency bandwidth audio signal is provided at an input terminal 18 to a gain control device 19. This gain control device is used by the user to control the overall reproduction level of the system through a volume control signal 31 determined by a user interface. The output of the gain control device 19 is connected to the input of a frequency crossover network 20 as well as to an input of a frequency-dependent analysis and weighting device 30. The individual frequency band-limited outputs of the crossover network 20 are connected individually to the inputs of gain control devices (or level adjustment means) 21, 22 and 23. In a system of a differing size, a different number of band-limited signals may be used. The instantaneous gain of said gain control devices is controlled by signals from the outputs of the frequency-dependent analysis and weighting device 30. The outputs of said gain control devices are connected individually to power amplifiers 24, 25 and 26. The outputs of said power amplifiers are connected to the inputs of loudspeaker drivers 27, 28, and 29. The frequency-dependent analysis and weighting device 30 uses multiple input signals in order to calculate the desired gains of the band-limited signals. These input signals include the user-determined level control signal 31, the level 37 of the program material output from the gain control device 19, the user-defined bass and treble control signals 32 and 33, a signal 33 representative of the background noise in the vehicle, a signal 34 representative of the speed of the vehicle and a signal 36 used to determine the desired dynamic range of the system according to such parameters as, but not exclusively, the reproduction level, the vehicle speed, and the background noise conditions.

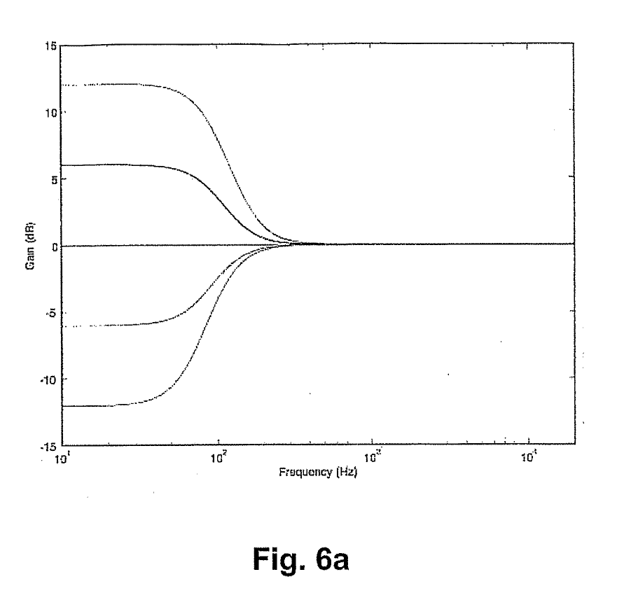

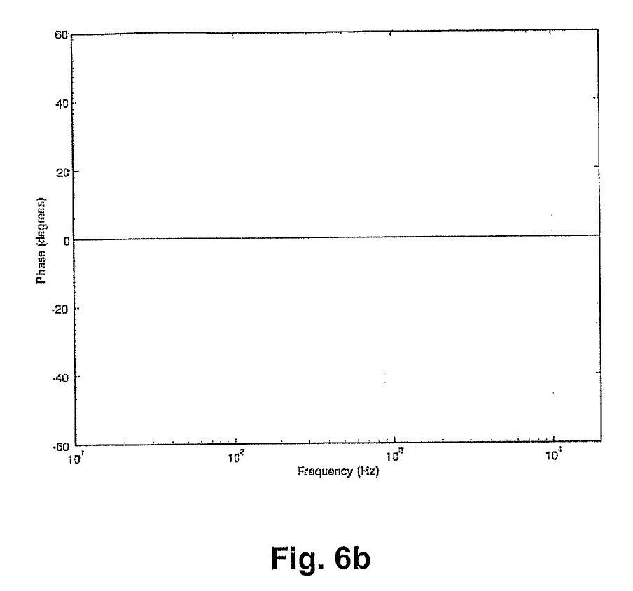

An example of the gain characteristics (i.e. gain (dB) as a function of frequency) and the corresponding phase characteristics (i.e. phase (degrees) as a function of frequency) for the entire acoustic output signal is shown in FIGS. 6a and 6b for various settings of the gain of a band-limited output. The phase response can thus be observed to be unchanged with changes in gain of the frequency band.

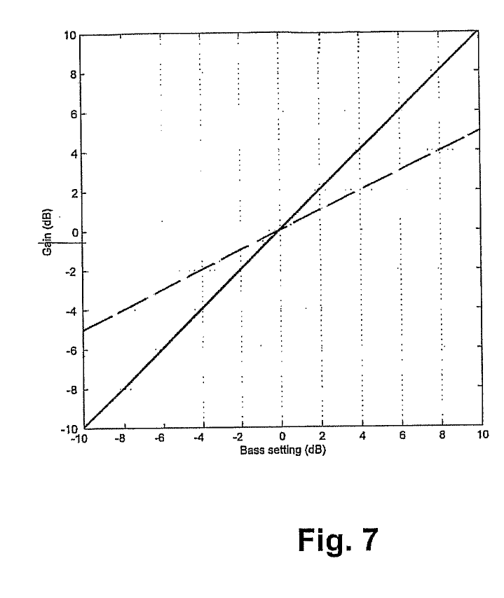

Referring to FIG. 7 there is shown an example of the use of the invention as a bass control for user-defined contouring of low-frequency content in an audio signal. In this case, the user would increase or decrease the bass content by means of a simple control device. This, in turn would determine the gain applied to the low-frequency output channel of the invention as is shown in FIG. 7. In this example, two different possible gain functions are shown to demonstrate the actual gain of the low-frequency output relative to the amount shown on the controller or user interface/remote control of the system.

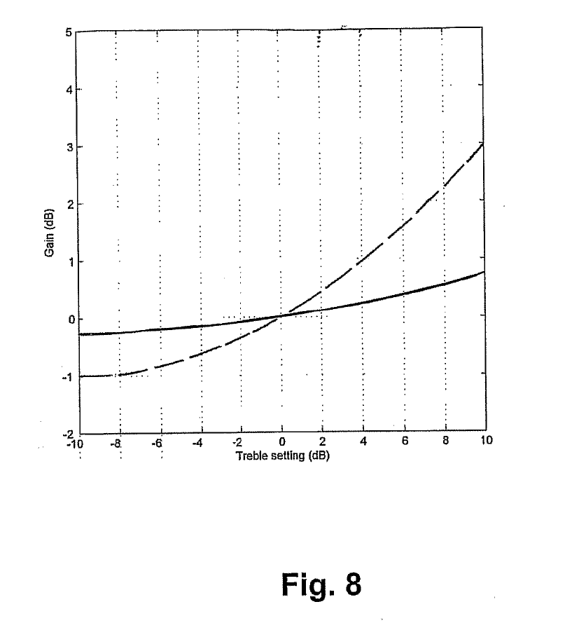

Referring to FIG. 8 there is shown an example of the use for the invention as a treble control for user-defined contouring of high-frequency content in an audio signal In this case, the user would increase or decrease the treble content by means of a simple control device This, in turn would determine the gain applied to the high-frequency output channel of the invention as is shown in FIG. 8. In this example, two different possible gain functions are shown to demonstrate the actual gain of the high-frequency output relative to the amount shown on the controller. As is shown, the relationship between the gain and the displayed value need not be linear.

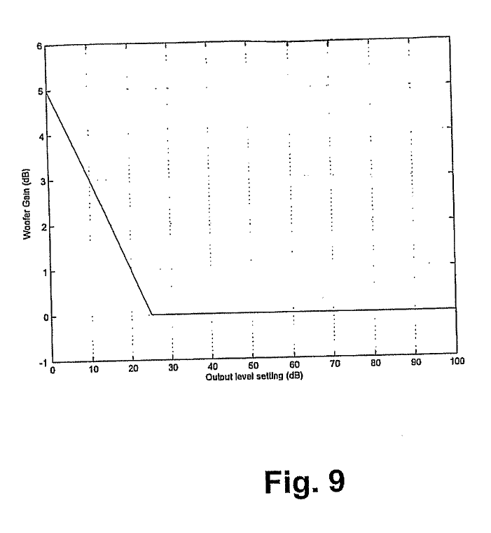

Referring to FIG. 9 there is shown an example of the use for the invention as an automatic loudness control for contouring of low-frequency content in an audio signal according to the user-controlled frequency-independent level. In this case, the bass content of the signal would be automatically increased at low listening levels to compensate for natural deficiencies (i.e. the equal loudness contours) in human hearing as is shown in FIG. 9. In this example, a possible gain function is shown to demonstrate the gain of the low-frequency output relative to the user-defined listening level.

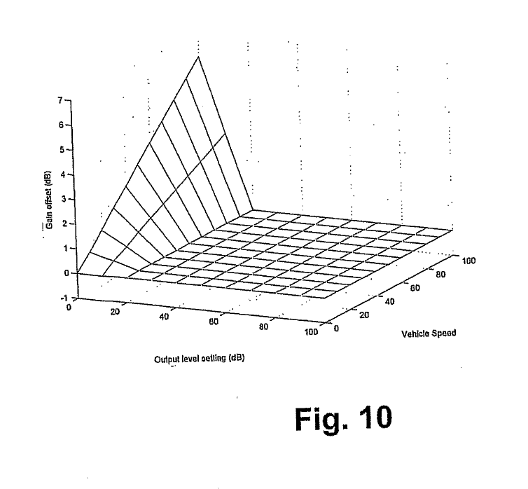

Referring to FIG. 10 there is shown an example of the use for the invention as a speed-compensation device for contouring of frequency-dependent gain in an audio signal according to the user-defined listening level and speed of a moving vehicle in an automotive audio system. In this example, a band-limited component of the signal is automatically increased at low listening levels and higher speeds to compensate for masking effects of background noise on the musical signal or other wanted sound signal as is shown in FIG. 10 In this example, the gain of a band-limited component of the signal is shown as a function of overall level and speed in percent of maximum speed.

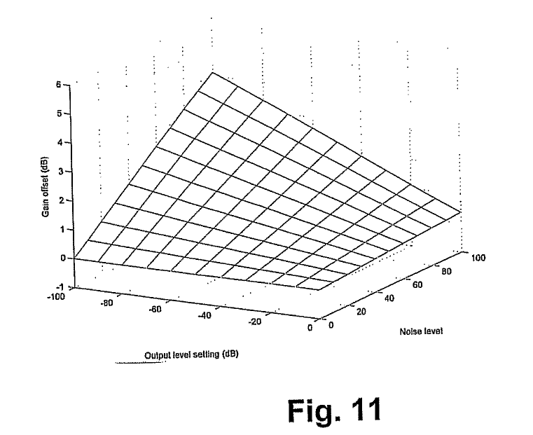

Referring to FIG. 11 there is shown an example of the use for the invention as a background noise compensation device for contouring of frequency-dependent gain in an audio signal according to the user-defined listening level and a measurement of an interfering background noise. In this example, a band-limited component of the signal is automatically increased at lower listening levels and higher noise levels to compensate for masking effects of background noise on the musical signal or other wanted sound signal as is shown in FIG. 11. In this example, the gain of the band-limited component of the signal is shown as a function of overall level and background noise in dBSPL.

Although not specifically shown in FIG. 5 it would furthermore be possible according to the invention to implement an embodiment comprising a limiter (AGC) function in one or more of the independent frequency channels obtained by the cross-over network 20 for instance by taking the particular output from the cross-over network 20 (for instance the input signal to the gain adjustment means 23) and use this signal—optionally via the frequency-dependent analysis and weighting network 30—to control the corresponding level adjustment means—in this case 23—thereby attempting to prevent the level of the signal provided to the corresponding power amplifier—in this case 26—from exceeding a certain value.

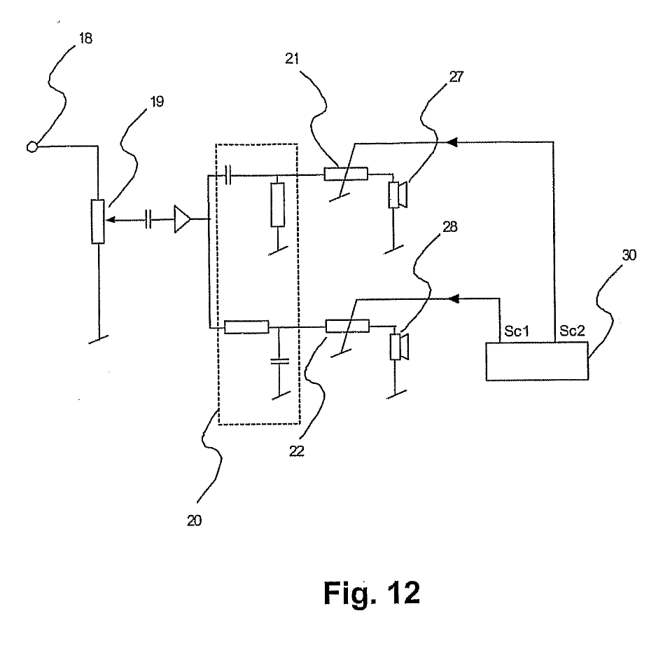

Although the invention has been described in detail in connection with an active loudspeaker system, in which each loudspeaker driver is driven by separate power amplifiers as shown in FIG. 5, the invention may also be extended systems comprising only one power amplifier and a traditional passive crossover network. An embodiment of the invention comprising a single power amplifier and a passive crossover network is shown schematically in FIG. 12. The system receives an audio signal at input terminal 18, which signal after a volume control 19 is provided to the power amplifier 37. At the output of the power amplifier 37 there is provided two channels passive crossover network 20 for dividing the frequency region in a low and high frequency region. Signals in the high frequency region are provided to a tweeter 27 and signals in the low frequency region are provided to a woofer 28. Between the respective output terminals of the crossover network 20 and the loudspeaker drivers 27, 28 there are inserted means, the resistance of which can be controlled by supply of a suitable control signal, for instance a DC voltage. Voltage dependent resistors (VDR's) could possibly be used as such controllable means. The control signals S_{c1} and S_{c2} are determined and supplied by the frequency-dependent analysis and weighting network 30.

1. A timbre and dynamic range adjustment method for an audio system, said method comprising the following steps:
(a) subdividing an audio signal into N frequency bands, each of said bands providing a band-limited output signal;
(b) adjusting the level of each of said output signals to obtain level-adjusted signals each having a desired timbre adjustment; and
(c) supplying each of said level-adjusted output signals to a separate transducer of a plurality of transducers so as to convert the level-adjusted output signals into sound signals emitted by said transducers so as to obtain a resulting magnide response for the system having reduced or eliminated audible phase artefacts.

2. Method according to claim 1, where said levels are adjustable by individual controllable level adjustment means in response to corresponding control signals from a frequency-dependent analysis and weighting network.

3. Method according to claim 2, where said control signals are based on input signals to said frequency-dependent analysis and weighting network relating to at least one of a group of control signals consisting of a user-determined level control signal, the level of program material output from a gain control device controlled by said level control signal, a user defined bass control signals, a user defined treble control signals, a control signal describing the background noise of the surroundings, a control signal describing the speed of a vehicle and a signal describing the dynamic range of at least one audio signal processed according to the method.

4. A timbre and dynamic range adjustment method according to claim 1 where said levels are manually controlled.

5. A timbre and dynamic range adjustment method according to claim 1 comprising the additional step of maintaining a maximum level for each of said level-adjusted output signals below a given pre-determined threshold level, whereby the risk of excessive loading of one or more of said transducers is reduced or eliminated.

6. A timbre and dynamic range adjustment device for an audio system, the device receiving an audio signal Si and providing N level-adjusted output signals, and the device comprising means for subdividing said audio signal Si into N frequency bands, each of said bands providing a band-limited output signal, wherein each of said band limited output signals is provided with adjustment means for adjusting the level of each of the band-limited output signals so as to obtain a desired timbre adjustment; whereby N level-adjusted output signals are provided and whereby a resulting magnitude response for the system is produced having reduced or eliminated audible phase distortion.

7. Device according to claim 6, where the gain of each of said adjustment means is controllable by means of individual control signals.

8. Device according to claim 6, further comprising a frequency-dependent analysis and weighting device providing said control signals to said adjustment means related to input signals supplied to the frequency-dependent analysis and weighting devices.

9. Device according to claim 8, where said input signals belong to at least one of a group of signals consisting of a user-determined level control signal, the level of program material output from a gain control device controlled by said level control signal, a user determined bass control signal, a user-defined treble control signal, a control signal describing the background noise of the surroundings, a control signal describing the speed of a vehicle and a signals describing the dynamic range of one at least one audio signal processed in the device.

10. Device according to claim 6, further comprising a gain control device for controlling the overall reproduction level of the audio signal provided by the device.

11. A system for adjusting the timbre and/or dynamic range of an audio signal generated by means of a plurality of loudspeaker drivers, the system comprising a timbre and dynamic range adjustment device according to claim 6, wherein each of said level-adjusted band-limited output signals provided by said device is either fed to separate power amplifiers, each driving at least one loudspeaker driver, oris fed directly to at least one of said loudspeaker driver.

12. A system according to claim 11 adapted for use in a vehicle and provided with at least one of means for sensing the speed of the vehicle and means for sensing interfering background noise.

13. A system according to claim 12, where said system includes means for sensing interfering background noise comprising at least one microphone placed inside the vehicle.

14. An audio reproduction system, comprising at least two channels, where at least one of the channels comprises a system according to claim 11.
